(19) United States
(12) Patent Application Publication
(10) Pub. No.: US 2004/0081054 A1
(43) Pub. Date: Apr. 29, 2004

(54) Finger grip for disk drive

(75) Inventor: Long V. Nguyen, San Jose, CA (US)

Correspondence Address: MICHAEL B. EINSCHLAG, ESQ., 25680 FERNHILL DRIVE, LOS ALTOS HILLS, CA, 94024, US

(73) Assignee: Riospring, Inc., Milpitas, CA

(21) Appl. No.: 10/687,057

(22) Filed: Oct. 16, 2003

Related U.S. Application Data
(60) Provisional application No. 60/420,632, filed on Oct. 22, 2002.

(51) Int. Cl. G11B 33/02; G11B 5/012; G11B 17/00; G06F 1/16; H05K 5/00; H05K 7/00

(52) U.S. Cl. 369/75.1; 360/97.01; 361/685

(57) ABSTRACT

One embodiment of the present invention is a small form factor disk drive for use in an appliance, which disk drive includes: a connector side, a removal side, and gripping sides; wherein the gripping sides include gripping mechanisms that are disposed along the gripping sides so that the gripping mechanisms are exposed whenever the appliance ejects the disk drive.

This application claims the benefit of U.S. Provisional Application No. 60/420,632, filed on Oct. 22, 2002, which is incorporated herein by reference.

### TECHNICAL FIELD OF THE INVENTION

One or more embodiments of the present invention relate generally to method and apparatus for gripping a disk drive.

### BACKGROUND OF THE INVENTION

There is a growing market demand for appliances in the form of consumer products like digital consumer products such as, for example and without limitation, digital cameras, personal digital assistants (“PDA”), smart phones, and so forth. These digital consumer products utilize memory and/or storage devices such as, for example and without limitation, compact flash memory, memory stick, smart media, and miniature hard disk drives. Consumers are demanding that such memory and/or storage devices provide ever increasing amounts of storage.

Small form factor memory and storage devices such as those, for example and without limitation, that conform to the “CF+ and Compact Flash Specification,” Revision 2, May 2003 issued by CompactFlash Association, Palo Alto, Calif. are regularly installed in, and removed from, various equipment such as, for example and without limitation, appliances. For example and without limitation, compact flash devices serve to store pictures taken by digital cameras, and are regularly installed in, and removed from, such digital cameras. Because of this, ease of installation and removal of such small form factor devices is a key feature for user convenience and satisfaction.

However, such compact flash form factor storage devices are not ergonomically designed. As is well known, current such small form factor memory and storage devices are notoriously difficult to remove from some host appliances (for example and without limitation, digital cameras) due to their small size and a lack of surfaces available for gripping adequately. For example, it is difficult to remove a compact flash card from a digital camera because the card typically does not protrude far enough from the camera body when ejected to provide enough gripping room for a user's fingers to grab on and remove it from the camera. As a result, users often use a foreign object such as, for example and without limitation, tweezers or a small screwdriver to help pry the compact flash card out of the camera. This problematic in that it is inconvenient and may lead to damaging the storage device as well as the digital consumer product in which it is used.

In addition to the above, the problem entailed in removing such small form factor devices is further complicated by the fact that a relatively large force may be required to remove such devices from some equipment or host appliances, and that such devices can be damaged if they are gripped improperly as they are removed. In further addition, individuals having various degrees of dexterity may have difficulty in maintaining a positive grip on such devices (especially when a large force is required to remove the device), thereby causing such devices to fall and be damaged.

In light of the above, there is a need to overcome one or more of the above-identified problems.

### SUMMARY OF THE INVENTION

One or more embodiments of the present invention satisfy one or more of the above-identified needs in the art. In particular, one embodiment of the present invention is a small form factor disk drive for use in an appliance, which disk drive comprises: a connector side, a removal side, and gripping sides; wherein the gripping sides include gripping mechanisms that are disposed along the gripping sides so that the gripping mechanisms are exposed whenever the appliance ejects the disk drive.

### BRIEF DESCRIPTION OF THE DRAWING

FIG. 1 shows a top view of a compact flash hard disk drive that includes finger grips that are fabricated in accordance with one or more embodiments of the present invention;

FIG. 2 shows a side view of the compact flash hard disk drive and one of the finger grips shown in FIG. 1; and

FIG. 3 shows an isometric view of the compact flash hard disk drive and one of the finger grips shown in FIG. 1.

### DETAILED DESCRIPTION

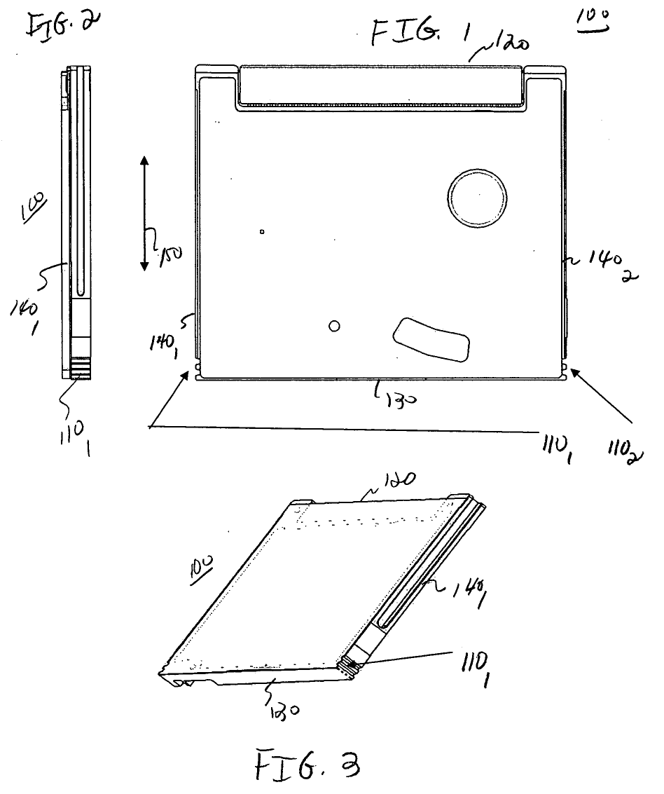

FIG. 1 shows a top view of compact flash hard disk drive 100. As shown in FIG. 1, compact flash hard disk drive 100 includes connector side 120, removal side 130, and gripping sides 140₁ and 140₂. As further shown in FIG. 1, gripping sides 140₁ and 140₂ include finger grips 110₁ and 110₂, respectively, that are fabricated in accordance with one or more embodiments of the present invention. Arrow 150 indicates a direction of insertion/removal of compact flash hard disk drive 100 into an appliance (for example and without limitation, a digital camera). In addition, FIG. 2 shows a side view of compact flash hard disk drive 100 and gripping side 140₁ with finger grip 110₁ shown in FIG. 1; and FIG. 3 shows an isometric view of compact flash hard disk drive 100 and gripping side 140₁ with finger grip 110₁ shown in FIG. 1.

As shown in FIGS. 1-3, finger grips 110₁ and 110₂ are disposed along a back portion of gripping sides 140₁ and 140₂ of compact flash hard disk drive 100, and are comprised of a series of protuberances in the form of “gear tooth” ridges. In addition, as shown in FIGS. 1-3, finger grips 110₁ and 110₂ are disposed near outermost comers of compact flash hard disk drive 100 that are opposite from connector side 120, where connector side 120 is a side of compact flash hard disk drive 100 that is inserted into the appliance to connect compact flash hard disk drive 100 with the appliance. The ridges of finger grips 110₁ and 110₂ are of a height which falls within the form factor of compact flash hard disk drive 100. Further, although the number of ridges may vary, embodiments may be fabricated wherein all the ridges are exposed when compact flash hard disk drive 100 is ejected from the appliance. The number of ridges to be used in a particular application may be determined routinely by one of ordinary skill in the art without undue experimentation. In particular, the size of the ridges, such as, for example, the width and depth may be fine-tuned for good gripping using a finger and/or fingernail.

It should be understood that one or more further embodiments of the present invention exist wherein finger grips 110₁ and 110₂ may be a series of protuberances having shapes other than “gear tooth” ridges. For example, in accordance with such one or more further embodiments of the present invention, finger grips 110₁ and 110₂ may comprise an array of bumps such as, for example and without limitation, spherical bumps or pyramid-shaped bumps.

Finger grips 110₁ and 110₂ may be fabricated utilizing any one of a number of methods that are well known to those of ordinary skill in the art such as, for example and without limitation, casting, molding or machining. In addition, in accordance with one or more embodiments of the present invention, a surface of finger grips 110₁ and 110₂ ridges may roughened—or include a high friction material such as, for example, a high friction tape—to provide enhanced friction to aid in gripping wherein the roughness or friction is sufficient to enable a user to overcome forces that retain the disk drive in an appliance with which it is used (suitable amounts of roughness or friction may be determined routinely by one of ordinary skill in the art without undue experimentation).

In accordance with one or more alternative embodiments of the present invention, finger grips 110₁ and 110₂ may be a rough or high friction surface without ridges wherein the roughness or friction is sufficient to enable a user to overcome forces that retain the disk drive in an appliance with which it is used (suitable amounts of roughness or friction may be determined routinely by one of ordinary skill in the art without undue experimentation). For example, in accordance with such one or more alternative embodiments, the outer surface of finger grips 110₁ and 110₂ may be tape with an adhesive that provides the desired amount of friction. Alternatively, finger grips 110₁ and 110₂ may be fabricated by treating the surface in accordance with any one of a number of methods that are well known to those of ordinary skill in the art to add grit and so forth.

Although various embodiments that incorporate the teachings of the present invention have been shown and described in detail herein, those skilled in the art can readily devise many other varied embodiments that still incorporate these teachings.

What is claimed is:

1. A small form factor disk drive for use in an appliance, which disk drive comprises:
a connector side, a removal side, and gripping sides;
wherein the gripping sides include gripping mechanisms that are disposed along the gripping sides so that the gripping mechanisms are exposed whenever the appliance ejects the disk drive.

2. The small form factor disk drive of claim 1 wherein the gripping mechanisms comprise a predetermined number of protuberances.

3. The small form factor disk drive of claim 2 wherein the protuberances are disposed within the form factor of the disk drive.

4. The small form factor disk drive of claim 2 wherein the protuberances comprise ridges.

5. The small form factor disk drive of claim 2 wherein the protuberances comprise an array of bumps.

6. The small form factor disk drive of claim 5 wherein the bumps are spherical bumps.

7. The small form factor disk drive of claim 5 wherein the bumps are pyramid-shaped bumps.

8. The small form factor disk drive of claim 2 wherein a surface of the protuberances have high friction.

9. A small form factor disk drive for use in an appliance, which disk drive comprises:
a connector side, a removal side; and gripping sides;
wherein the gripping sides include gripping mechanisms that are disposed adjacent to the removal side.

10. The small form factor disk drive of claim 1 wherein the gripping mechanisms comprise a rough or high friction surface.
